(19) United States
(12) Patent Application Publication
(10) Pub. No.: US 2014/0367774 A1
(43) Pub. Date: Dec. 18, 2014

(54) Semiconductor Devices Having Partially Oxidized Gate Electrodes

(71) Applicant: Samsung Electronics Co., Ltd., Suwon-si (KR)

(72) Inventors: Jong-Ryeol Yoo, Osan-si (KR); Jun-Noh Lee, Hwaseong-si (KR); Dong-Chan Kim, Anyang-si (KR); Han-Jin Lim, Seoul (KR)

(21) Appl. No.: 14/294,412

(22) Filed: Jun. 3, 2014

(30) Foreign Application Priority Data
Jun. 13, 2013 (KR) 10-2013-0067887

(51) Int. Cl. H01L 29/423; H01L 29/49

(52) U.S. Cl. CPC H01L 29/4236; H01L 29/4958
USPC 257/330

(57) ABSTRACT

Semiconductor devices are provided including a first trench in a semiconductor substrate; a first insulating film in the first trench; a first conductive film on the first insulating film, the first conductive film having upper and lower portions and filling at least a portion of the first trench; and a first work function adjustment film having first and second portions, a first lower work function adjustment film portion and a first upper work function adjustment portion. The first lower work function adjustment film portion overlaps the lower portion of the first conductive film and the first upper work function adjustment film portion overlaps the upper portion of the first conductive film between the first insulating film and the first conductive film.

### CROSS-REFERENCE TO RELATED APPLICATION

This application claims priority to Korean Patent Application No. 10-2013-0067887, filed Jun. 13, 2013, the disclosure of which is hereby incorporated herein by reference as set forth in its entirety.

### FIELD

The present inventive concept relates generally to semiconductor devices and, more particularly, to semiconductor devices having gate electrode positioned in a trench.

### BACKGROUND

A buried channel array transistor (BCAT) may include a gate electrode in a trench and typically improves short channel effects. However, the characteristics of the BCAT may differ depending on the depth of the trench, i.e. how far the gate electrode is buried from the surface of a substrate. For example, a gate induced drain leakage (GIDL) or the amount of current of the BCAT may differ.

### SUMMARY

Some embodiments of the present inventive concept provide semiconductor devices including a first trench in a semiconductor substrate; a first insulating film in the first trench; a first conductive film on the first insulating film, the first conductive film having upper and lower portions and filling at least a portion of the first trench; and a first work function adjustment film having first and second portions, a first lower work function adjustment film portion and a first upper work function adjustment portion. The first lower work function adjustment film portion overlaps the lower portion of the first conductive film and the first upper work function adjustment film portion overlaps the upper portion of the first conductive film between the first insulating film and the first conductive film.

In further embodiments, a first work function of the first lower work function adjustment film portion may be larger than a second work function of the first upper work function adjustment film portion.

In still further embodiments, an upper surface of the first conductive film may be free of the first upper work function adjustment film.

In some embodiments, profiles of both side surfaces of the first lower work function adjustment film portion and the first upper work function adjustment film portion may be continued.

In further embodiments, an impurity region may be provided on both sides of the first trench. The first upper work function adjustment film portion may overlap the impurity region.

In still further embodiments, a depth from an upper surface of the semiconductor substrate to a bottom surface of the impurity region may be a first depth. A depth from the upper surface of the substrate to the lowermost portion of the first upper work function adjustment film may be a second depth. The second depth may be larger than the first depth.

In some embodiments, the first lower work function adjustment film portion may include a material including one of Ti, Ta, W, and TiSi. The first upper work function adjustment film portion may include a material that is an oxidized version of the material of lower work function adjustment film portion.

In further embodiments, a height of an upper portion of the first conductive film may be a first height and a height of the first upper work function adjustment film may be a second height. The first height and the second height may be substantially the same. The first insulating film may include silicon oxide.

In still further embodiments, the semiconductor substrate may further include first and second regions. The first trench, the first insulating film, the first work function adjustment film, and the first conductive film may be provided in the first region. The semiconductor device may further include a second trench in the second region; a second insulating film in the second trench; a second conductive film on the second insulating film and filling at least a portion of the second trench; and a second work function adjustment film between the second insulating film and the second conductive film. The second trench, the second insulating film, the second conductive film and the second work function adjustment film may be provided in the second region of the semiconductor substrate. The first work function adjustment film may be an n-type work function adjustment film and the second work function adjustment film may be a p-type work function adjustment film.

Still further embodiments of the present inventive concept provide semiconductor devices including a trench in a semiconductor substrate; a first insulating film in the trench;

a first conductive film on the first insulating film, the first conductive film having upper and lower portions and filling a portion of the trench; a second conductive film, overlapping the lower portion of the first conductive film between the first insulating film and the first conductive film; and a second insulating film including a material including an oxidized version of a material of the second conductive film and overlapping the upper portion of the first conductive film between the first insulating film and the first conductive film.

In some embodiments, an upper surface of the first conductive film may be free of the second insulating film.

In further embodiments, profiles of both side surfaces of the second insulating film and the second conductive film may be continued.

In still further embodiments, an impurity region may be provided on both sides of the trench. The second insulating film may overlap the impurity region.

Some embodiments of the present inventive concept provide semiconductor devices including a semiconductor substrate defining a trench; and a gate electrode in the trench having a first portion and a second portion on the first portion, the first portion of the gate electrode including a first material and the second portion of the gate electrode including an oxidized version of the first material.

In further embodiments, the device further includes a work function adjustment film in the trench between the semiconductor substrate and the gate electrode. The work function adjustment film may have a first portion and a second portion on the first portion. The first portion of the gate electrode may be adjacent the first portion of the work function adjustment film and the second portion of the gate electrode may be adjacent the second portion of the work function adjustment film.

In still further embodiments, a height of the second portion of the gate electrode and a height of the second portion of the work function adjustment film may be substantially equal.

In some embodiments, a work function of the first portion of the work function adjustment film may be different from a work function of the second portion of the work function adjustment film.

In further embodiments, the work function of the first portion of the work function adjustment film may be larger than the work function of the second portion of the work function adjustment film.

### BRIEF DESCRIPTION OF THE DRAWINGS

The above and other objects, features and advantages of the present inventive concept will be more apparent from the following detailed description taken in conjunction with the accompanying drawings, in which:

FIG. 1 is a cross-section illustrating semiconductor devices according to some embodiments of the present inventive concept.

FIG. 2 is a cross-section illustrating semiconductor devices according to some embodiments of the present inventive concept.

FIG. 3 is a cross-section illustrating semiconductor devices according to some embodiments of the present inventive concept.

FIG. 4 is a cross-section illustrating semiconductor devices according to some embodiments of the present inventive concept.

FIG. 5 is a layout diagram illustrating semiconductor devices according to according to some embodiments of the present inventive concept.

FIG. 6 is a cross-section taken along line A-A′ of FIG. 5.

FIGS. 7A and 7B are cross-sections illustrating semiconductor devices according to some embodiments of the present inventive concept.

FIG. 8 is a cross-section illustrating semiconductor devices according to some embodiments of the present inventive concept.

FIG. 9 is a block diagram illustrating an example of an electronic system including semiconductor devices according to some embodiments of the present inventive concept.

FIG. 10 is a block diagram illustrating an example of a memory card including semiconductor devices according to some embodiments of the present inventive concept.

FIGS. 11 to 16 are cross-sections illustrating processing steps in the fabrication of semiconductor devices according to some embodiments of the present inventive concept.

FIGS. 17 to 19 are cross-sections illustrating processing steps in the fabrication of semiconductor devices according to some embodiments of the present inventive concept.

FIGS. 20 to 22 are cross-sections illustrating processing steps in the fabrication of semiconductor devices according to some embodiments of the present inventive concept.

### DETAILED DESCRIPTION OF THE EMBODIMENTS

The present inventive concept will now be described more fully hereinafter with reference to the accompanying drawings, in which preferred embodiments of the inventive concept are shown. This inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art. The same reference numbers indicate the same components throughout the specification. In the attached figures, the thickness of layers and regions is exaggerated for clarity.

It will be understood that when an element or layer is referred to as being “connected to,” or “coupled to” another element or layer, it can be directly connected to or coupled to another element or layer or intervening elements or layers may be present. In contrast, when an element is referred to as being “directly connected to” or “directly coupled to” another element or layer, there are no intervening elements or layers present. Like numbers refer to like elements throughout. As used herein, the term “and/or” includes any and all combinations of one or more of the associated listed items.

It will also be understood that when a layer is referred to as being “on” another layer or substrate, it can be directly on the other layer or substrate, or intervening layers may also be present. In contrast, when an element is referred to as being “directly on” another element, there are no intervening elements present.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present inventive concept.

The use of the terms “a” and “an” and “the” and similar referents in the context of describing the inventive concept (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which this inventive concept belongs. It is noted that the use of any and all examples, or exemplary terms provided herein is intended merely to better illuminate the inventive concept and is not a limitation on the scope of the inventive concept unless otherwise specified. Further, unless defined otherwise, all terms defined in generally used dictionaries may not be overly interpreted.

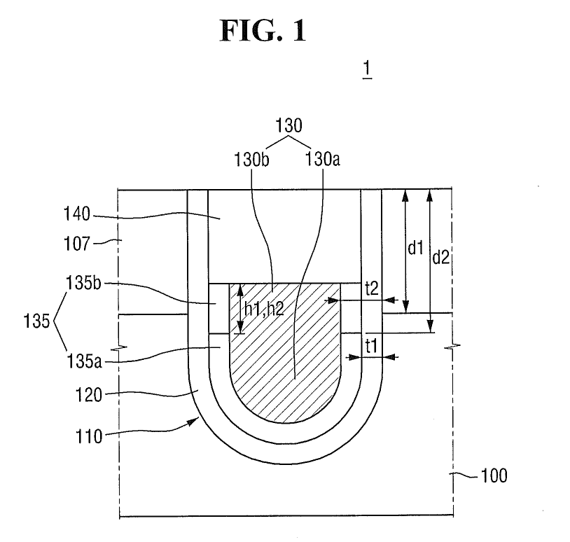

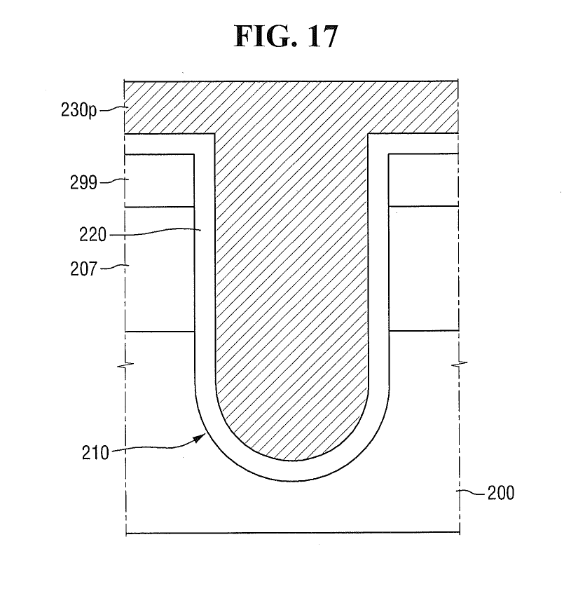

Some embodiments of the present inventive concept provide semiconductor devices and related methods that provide improved gate induced drain leakage (GIDL) characteristics and/or reduce the resistance of a gate electrode through oxidization of a part of a conductive electrode. Further embodiments may provide a reduce resistance of a metal wiring in a back end of line (BEOL) as will be discussed further below with respect to FIGS. 1 through 22.

Referring first to FIG. 1, a cross-section illustrating semiconductor devices in accordance with embodiments of the present inventive concept will be discussed. As illustrated in FIG. 1, semiconductor devices 1 according to some embodiments of the present inventive concept include a substrate 100, a first trench 110, a first insulating film 120, a first work function adjustment film 135, a first gate electrode 130, and a first capping film 140.

The substrate 100 may have a structure in which a base substrate and an epitaxial layer are laminated, however, it will be understood that embodiments of the inventive concept are not limited thereto. For sake of example, the substrate 100 is discussed herein as being a silicon substrate. However, it will be understood that the substrate 100 is not limited to this configuration. For example, the substrate 100 may be a silicon substrate, a gallium arsenide substrate, a silicon germanium substrate, a ceramic substrate, a quartz substrate, or a glass substrate for display without departing from the scope of the present application. In some embodiments, the substrate 100 may also be a semiconductor on insulator (SOI) substrate. Further, the substrate 100 has a first conductivity type, for example, P-type, but is not limited thereto.

The first trench 110 is formed in the substrate 100. The first trench 110 may have various shapes. For example, the first trench 110, as described, may have a round-shape connection portion between a bottom surface and a sidewall. Further, the first trench 110 may have an inclined sidewall with a predetermined angle.

The first insulating film 120 is on the first trench 110. In other words, the first insulating film 120 may be formed along the sidewall and the bottom surface of the first trench 110. The first insulating film 120 may include at least one of silicon oxide, silicon nitride, silicon oxynitride, and a high-k material. The high-k material may include at least one of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, but is not limited thereto.

The first gate electrode 130 is on the first insulating film 120. The first gate electrode 130 may be formed in the first trench 110 so that it does not completely fill the first trench 110, but fills at least a portion of the first trench 110. The first gate electrode 130 may be in a recessed shape. An upper surface of the first gate electrode 130 may be lower than an upper surface (surface) of the substrate 100. The first gate electrode 130 may be formed using a conductive material, for example, metal or polysilicon, but is not limited thereto. In some embodiments, the first gate electrode includes metal, for example, tungsten (W).

The first gate electrode 130 includes a lower portion 130a and an upper portion 130b. The lower portion 130a of the first gate electrode and the upper portion 130b of the first gate electrode are formed at the same level. As used herein, “the same level” refers to being formed in the same fabricating process.

The first work function adjustment film 135 is positioned between the first insulating film 120 and the first gate electrode 130. The first work function adjustment film 135 may be formed along at least a portion of a sidewall of the first trench 110 and a bottom surface of the first trench 110.

The first work function adjustment film 135 includes a first lower work function adjustment film 135a and a first upper work function adjustment film 135b. The first lower work function adjustment film 135a overlaps the lower portion 130a of the first gate electrode, but does not overlap the upper portion 130b of the first gate electrode. The first upper work function adjustment film 135b overlaps the upper portion 130b of the first gate electrode. In other words, the first gate electrode 130 may be divided into the upper portion 130b and the lower portion 130a around a boundary surface between the first upper work function adjustment film 135b and the first lower work function adjustment film 135a.

The upper portion 130b of the first gate electrode has a first height h1, and the first upper work function adjustment film 135b has a second height h2. In the semiconductor device 1 according to some embodiments of the present inventive concept, the height h1 of the upper portion 130b of the first gate electrode is substantially equal to the height h2 of the first upper work function adjustment film 135b.

As illustrated in FIG. 1, the upper surface of the upper portion 130b of the first gate electrode and the upper surface of the first upper work function adjustment film 135b may be put on the same plane, but are not limited thereto. On the side surface that is adjacent to the first gate electrode 130, the depth measured from the upper surface of the substrate to the first upper work function adjustment film 135b is substantially equal to the depth measured from the upper surface of the substrate 100 to the first gate electrode. However, on the side surface that is adjacent to the first insulating film 120, the depth measure from the upper surface of the substrate 100 to the first upper work function adjustment film 135b may be greater than the depth measured from the upper surface of the substrate 100 to the first gate electrode 130. In other words, the upper surface of the first upper work function adjustment film 135b may be inclined at a predetermined angle against the upper surface of the first gate electrode 130.

Profiles of both side surfaces of the first upper work function adjustment film 135b and the first lower work function adjustment film 135a are continued. In particular, at a point where the first upper work function adjustment film 135b and the first lower work function adjustment film 135a meet, inclinations of the both side surfaces of the first upper work function adjustment film 135b and the first lower work function adjustment film 135a are substantially similar, if not equal, to each other. Furthermore, at the point where the first upper work function adjustment film 135b and the first lower work function adjustment film 135a meet, the width of the first upper work function adjustment film 135b and the width of the first lower work function adjustment film 135a are substantially equal to each other, and the first upper work function adjustment film 135b entirely overlaps the first lower work function adjustment film 135a.

The first upper work function adjustment film 135b is not formed on the upper surface of the first gate electrode 130. In other words, the first upper work function adjustment film 135b is formed on the side surface of the upper portion 130b of the first gate electrode, but may not be formed on the upper portion 130b of the first gate electrode.

The first lower work function adjustment film 135a and the first upper work function adjustment film 135b may include the same metal. As reference to herein, “metal” refers to both pure metal element and metal silicide.

The first lower work function adjustment film 135a may include one of TiN, TaN, WN, and TiSiN. The first upper work function adjustment film 135b includes a material that may be obtained by oxidizing the first lower work function adjustment film 135a. In other words, the first upper work function adjustment film 135b may include one oxide or oxynitride selected from the group including, for example, titanium (Ti), tantalum (Ta), tungsten (W), and titanium silicide (TiSi). The first work function adjustment film 135 may include the first upper work function adjustment film 135b and the first lower work function adjustment film 135a, which are made of different materials.

A work function of the first lower work function adjustment film 135a is a first work function, and a work function of the first upper work function adjustment film 135b is a second work function. In semiconductor devices according to some embodiments of the present inventive concept, the first work function of the first lower work function adjustment film 135a is different from the second work function of the first upper work function adjustment film 135b. In particular, the first work function of the first lower work function adjustment film 135a is larger than the second work function of the first upper work function adjustment film 135b. In other words, the first work function adjustment film 135 includes the first lower work function adjustment film 135a and the first upper work function adjustment film 135b, which have different work functions.

In other words, in the semiconductor device 1 according to some embodiments of the present inventive concept, an effective work function of a laminated body of the first gate electrode 130 and the first upper work function adjustment film 135b formed on the first insulating film 120 is smaller than an effective work function of a laminated body of the first gate electrode 130 and the first lower work function adjustment film 135a formed on the first insulating film 120.

The first capping film 140 may fill the first trench 110 on the first work function adjustment film 135 and the first gate electrode 130. In other words, the first capping film 140 is formed on the first upper work function adjustment film 135b and the upper portion 130b of the first gate electrode. The first capping film 140 may be, for example, an oxide film, a nitride film, or an oxynitride film, but is not limited thereto.

A first source/drain 107 is formed on both sides of the first trench 110. For example, if the semiconductor device 1 according to some embodiments of the present inventive concept is an N-type transistor, the first source/drain 107 may be doped with an N-type impurity.

The first source/drain 107 may overlap the first work function adjustment film 135. In particular, the first source/drain 107 may overlap the first upper work function adjustment film 135b.

The depth measured from the upper surface of the substrate 100 to a bottom surface of the first source/drain 107 is a first depth d1, and the depth measured from the upper surface of the substrate 100 to the lowermost portion of the first upper work function adjustment film 135b is a second depth d2. In the semiconductor device 1 according to some embodiments of the present inventive concept, the depth d2 measured from the upper surface of the substrate 100 to the lowermost portion of the first upper work function adjustment film 135b is deeper than the depth d1 measured from the upper surface of the substrate 100 to the bottom surface of the first source/drain 107. In other words, the first upper work function adjustment film 135b does not entirely overlap the first source/drain 107, but only a part of the first work function adjustment film 135b may overlap the first source/drain 107.

In the semiconductor device 1 according to some embodiments of the present inventive concept, the first lower work function adjustment film 135a that includes metal nitride may be a conductive film and the first upper work function adjustment film 135b that includes the metal oxide may be an insulating film in the first work function adjustment film 135.

In other words, the first lower work function adjustment film 135a, which is arranged between the first insulating film 120 and the first gate electrode 130 and overlaps the lower portion 130a of the first gate electrode, may serve as a gate electrode together with the lower portion 130a of the first gate electrode. However, the first upper work function adjustment film 135b, which is arranged between the first insulating film 120 and the first gate electrode 130 and overlaps the upper portion 130b of the first gate electrode, may serve as a gate insulating film together with the first insulating film 120.

A buried channel array transistor (BCAT) illustrated in FIG. 1 may include a first portion that is composed of the first insulating film 120, the first lower work function adjustment film 135a, and the lower portion 130a of the first gate electrode, and a second portion that is composed of the first insulating film 120, the first upper work function adjustment film 135b, and the upper portion 130b of the first gate electrode.

In the first portions 120, 135a, and 130a of the BCAT, the first insulating film 120 serves as a gate insulating film. However, in the second portions 120, 135b, and 130b of the BCAT, the first insulating film 120 and the first upper work function adjustment film 135b serve as the gate insulating film. In other words, the gate insulating film of the first portions 120, 135a, and 130a of the BCAT has a first thickness t1, and the gate insulating film of the second portions 120, 135b, and 130b of the BCAT has a second thickness d2.

The thickness t1 of the gate insulating film of the first portions 120, 135a, and 130a of the BCAT is thinner than the thickness t2 of the gate insulating film of the second portions 120, 135b, and 130b of the BCAT.

As further illustrated in FIG. 1, the first portions 120, 135a, and 130a of the BCAT and the second portions 120, 135b, and 130b of the BCAT may have different work functions. The work function of the first portions 120, 135a, and 130a of the BCAT may be larger than the work function of the second portions 120, 135b, and 130b of the BCAT.

Details with respect to the GIDL) characteristics of the semiconductor device 1 according to some embodiments of the present inventive concept will now be discussed. First, since the first work function adjustment film 135 includes the first upper work function adjustment film 135b and the first lower work function adjustment film 135a, which have different work functions, the GIDL characteristics can be improved, and the junction leakage current characteristics can be maintained.

In particular, if the work function of the gate electrode is increased, the junction leakage current is decreased. In contrast, if the work function of the gate electrode is increased, an electric field that is induced in the gate insulating film is increased in a portion that overlaps the source/drain, and thus the GIDL characteristics may be deteriorated.

However, if the first work function adjustment film 135 is formed to include the first upper work function adjustment film 135b and the first lower work function adjustment film 135a, which have different work functions, the GIDL characteristics can be improved without deterioration of the junction leakage current.

In other words, in a portion that is used as a channel region of the BCAT, the first lower work function adjustment film 135a having the work function that is larger than the work function of the first upper work function adjustment film 135b is arranged. Through this, the deterioration of the junction leakage current does not occur, but the junction leakage current characteristics can be maintained. However, in a portion that overlaps the first source/drain 107, the first upper work function adjustment film 135b having the work function that is smaller than the work function of the first lower work function adjustment film 135a is arranged, and thus a flatband voltage is decreased. If the flatband voltage is decreased as described above, the strength of the electric field that is included in the first insulating film 120 is reduced, and thus the GIDL characteristics may be improved.

Next, the thickness t2 of the gate insulating film of the BCAT in the vicinity of the first source/drain 107 is thicker than the thickness t1 of the gate insulating film of the BCAT in the channel region.

Since the gate insulating film of the BCAT in the vicinity of the first source/drain 107 corresponds to the first insulating film 120 and the first upper work function adjustment film 135b, the thickness of the gate insulating film is increased. If the thickness of the gate insulating film is increased, the strength of the electric field that is induced in the gate insulating film, i.e., the first insulating film 120 and the first upper work function adjustment film 135b, is decreased. Through this, the GIDL characteristics of the BCAT may be improved.

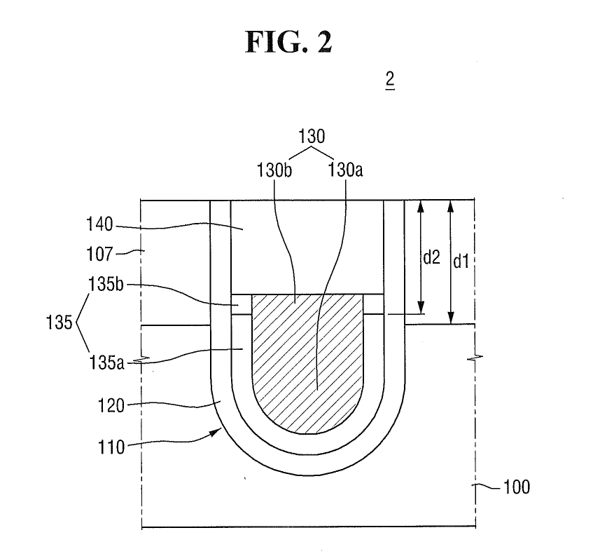

Referring now to FIG. 2, a semiconductor device according to some embodiments of the present inventive concept will be discussed. As is clear, many aspects of embodiments illustrated in FIGS. 1 and 2 are similar, thus, details with respect to the similar elements will not be repeated herein in the interest of brevity. FIG. 2 is a cross-section illustrating semiconductor devices according to some embodiments of the present inventive concept.

As illustrated in FIG. 2, the depth measured from the upper surface of the substrate 100 to the bottom surface of the first source/drain 107 is the first depth d1, and the depth measured from the upper surface of the substrate 100 to the lowermost portion of the first upper work function adjustment film 135b is the second depth d2.

In a semiconductor device 2 according to some embodiments of the present inventive concept, the first upper work function adjustment film 135b entirely overlaps the first source/drain 107. The depth d2 measured from the upper surface of the substrate 100 to the lowermost portion of the first upper work function adjustment film 135b may be shallower than the depth d1 measured from the upper surface of the substrate 100 to the bottom surface of the first source/drain 107, but is not limited thereto. In other words, the depth d2 measured from the upper surface of the substrate 100 to the lowermost portion of the first upper work function adjustment film 135b may also be substantially equal to the depth d1 measured from the upper surface of the substrate 100 to the bottom surface of the first source/drain 107.

As illustrated in FIG. 2, the first source/drain 107 may overlap both the first upper work function adjustment film 135b and the first lower work function adjustment film 135a, which have different work functions.

Although the first lower work function adjustment film 135a having the work function that is larger than the work function of the first upper work function adjustment film 135b may overlap a part of the first source/drain 107, the GIDL characteristics of the semiconductor device 2 according to some embodiments of the present inventive concept can be improved. If the first upper work function adjustment film 135b having a relatively small work function of the first work function adjustment film 135 overlaps the first source/drain, the strength of the electric field that is induced in the gate insulating films 120 and 135b of the second portions 120, 135b, and 130b of the BCAT is decreased, and thus the GIDL characteristics may be improved.

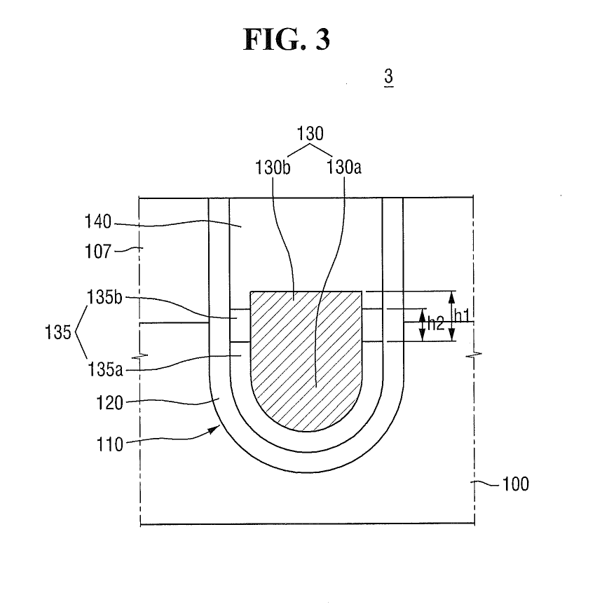

Referring now to FIG. 3, a semiconductor device according to some embodiments of the present inventive concept will be described. FIG. 3 is a cross-section illustrating semiconductor devices according to some embodiments of the present inventive concept. As illustrated in FIG. 3, in a semiconductor device 3 according to some embodiments of the present inventive concept, a first gate electrode 130 projects higher than the upper surface of the first work function adjustment film 135. However, the upper surface of the first gate electrode 130 may be lower than the upper surface of the substrate 100.

The upper portion 130b of the first gate electrode has a first height h1, and the first upper work function adjustment film 135b may have a second height h2. In the semiconductor device 3 according to some embodiments of the present inventive concept, the height h1 of the upper portion 130b of the first gate electrode is higher than the height h2 of the first upper work function adjustment film 135b.

The upper surface of the first gate electrode 130 is not put on the same plane as the upper surface of the first upper work function adjustment film 135b. A profile of the upper surface of the first upper work function adjustment film 135b and a profile of the upper surface of the first gate electrode 130 are discontinuous. In other words, there is a step height between the upper surface of the first gate electrode 130 and the first upper work function adjustment film 135b.

Since the first gate electrode 130 projects to be higher than the first work function adjustment film 135, a gap may be formed between the first gate electrode 130 and the first insulating film 120.

The gap formed between the first gate electrode 130 and the first insulating film 120 may be filled with the first capping film 140. In other words, a part of the first capping film 140 may be interposed between the first gate electrode 130 and the first insulating film 120, and may be surrounded by the first insulating film 120, the first upper work function adjustment film 135b, and a side surface of the first gate electrode 130.

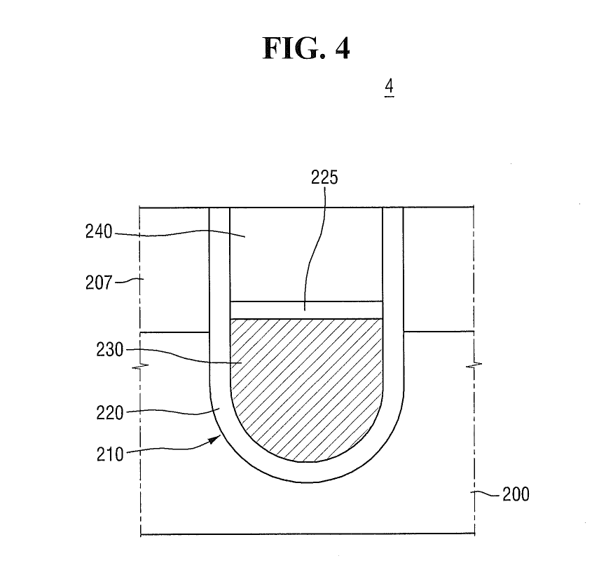

Referring now to FIG. 4, a semiconductor device according to some embodiments of the present inventive concept will be discussed. FIG. 4 is a cross-section illustrating semiconductor devices according to some embodiments of the present inventive concept. As illustrated in FIG. 4, a semiconductor device 4 according to some embodiments of the present inventive concept includes a substrate 200, a second trench 210, a second insulating film 220, a second gate electrode 230, a second capping film 240, and an electrode oxide film 225.

It will be understood that the substrate 200 may have a structure in which a base substrate and an epitaxial layer are laminated, however, embodiments of the present inventive concept is not limited thereto. The substrate 200 may be, for example, a silicon substrate, a gallium arsenide substrate, a silicon germanium substrate, a ceramic substrate, a quartz substrate, or a glass substrate for display without departing from the present inventive concept. The substrate 100 may also be an Semiconductor On Insulator (SOI) substrate. Hereinafter, a silicon substrate is described as an example. Further, the substrate 200 may be of a first conductivity type, for example, P-type, but is not limited thereto.

The second trench 210 is formed in the substrate 200. The second trench 210 may have various shapes. For example, the second trench 210, as described, may have a round-shape connection portion between a bottom surface and a sidewall, but is not limited thereto.

The second insulating film 220 is formed on the second trench 110 along the sidewall and the bottom surface of the second trench 210. The second insulating film 220 may include at least one of silicon oxide, silicon nitride, silicon oxynitride, and a high-k material.

The second gate electrode 230 is formed on the second insulating film 220. The second gate electrode 230 may be formed in the second trench 210 so that it does not completely fill the second trench 210, but fills a portion of the second trench 210. The second gate electrode 230 may be in a recessed shape. The second gate electrode 230 may include metal oxide, and may include, for example, one of TiN, TaN, Wn, and TiSiN.

The electrode oxide film 225 is formed on the second gate electrode 230. The electrode oxide film 225 is formed in the second trench 210. FIG. 4 illustrates that the depth measured from the upper surface of the substrate 200 to the lowermost portion of the electrode oxide film 225 is shallower than the depth measured from the upper surface of the substrate 200 to the lowermost portion of a second source/drain 207, but is not limited thereto.

The electrode oxide film 225 includes a material obtained by oxidizing the second gate electrode 230. For example, the electrode oxide film 225 may include one oxide or oxynitride selected from the group including titanium (Ti), tantalum (Ta), tungsten (W), and titanium silicide (TiSi). In other words, the second gate electrode 230 and the electrode oxide film 225 may include the same metal.

The second capping film 240 may be formed on the electrode oxide film 225 to fill the second trench 210. The second capping film 240 may be, for example, an oxide film, a nitride film, or an oxynitride film, but is not limited thereto. The second source/drain 207 may be formed on both sides of the second trench 210 in the substrate 200.

While the electrode oxide film 225 is formed, a defect that is formed on the surface of the second insulating film 220 may be cured. Through this, the GIDL characteristics of the semiconductor device 4 according to some embodiments of the present inventive concept can be improved.

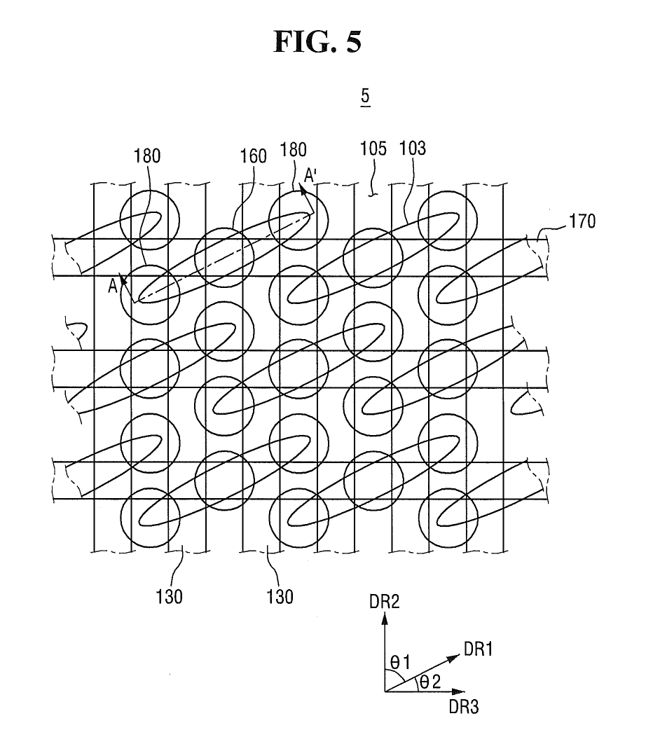

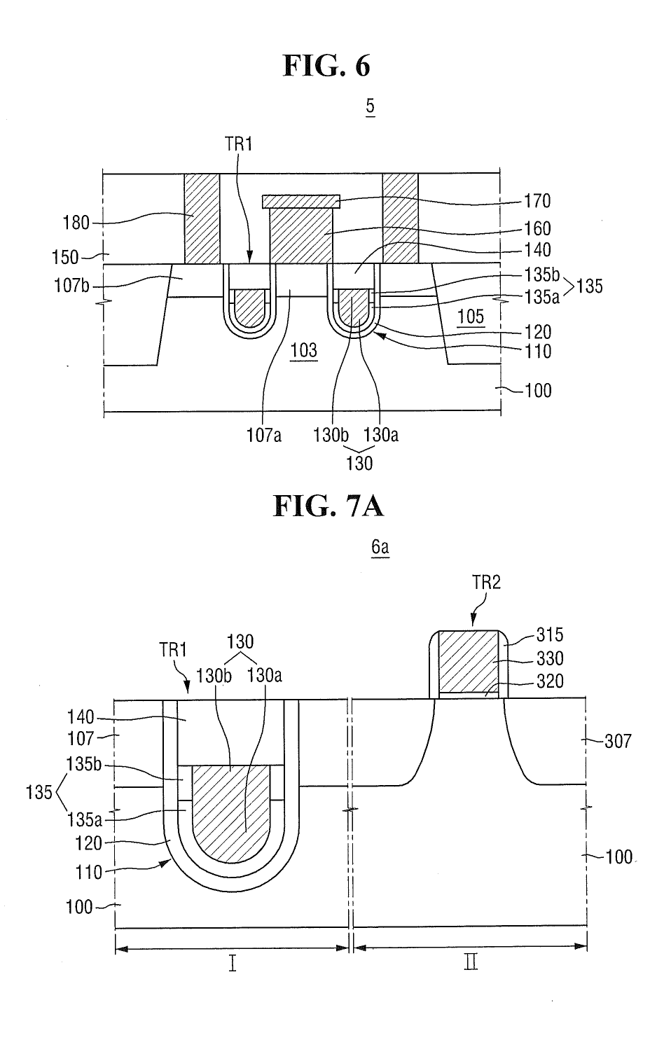

Referring now to FIGS. 5 and 6, a semiconductor device according to some embodiments of the present inventive concept will be discussed. FIG. 5 is a layout diagram illustrating a semiconductor device according to some embodiments of the present inventive concept, and FIG. 6 is a cross-section taken along line A-A′ of FIG. 5. As an example of a semiconductor device according to some embodiments of the present inventive concept, a Dynamic Random Access Memory (DRAM) is illustrated, however, it will be understood that embodiments of the present inventive concept are not limited thereto.

As illustrated in FIGS. 5 and 6, in a semiconductor device 5 according to some embodiments of the present inventive concept, a unit activate region 103 is defined by forming an isolation region 105 in the substrate 100.

In particular, the unit active region 103 is formed to extend in a first direction DR1, the first gate electrode, i.e., word line, 130 is formed to extend in a second direction DR2 that forms an acute angle with the first direction DR1, and a bit line 170 is formed to extend in a third direction DR3 that forms an acute angle with the first direction DR1.

In these embodiments, the angle in the case where one specific direction and another specific direction form a predetermined angle with each other means a smaller one of two angles which occur through crossing of two directions. For example, if angles which may occur through crossing of two directions are 120° and 60°, the angle means 60°. Accordingly, as illustrated in FIG. 5, the angle formed by the first direction DR1 and the second direction DR2 is θ1, and the angle formed by the first direction DR1 and the third direction DR3 is θ2.

As discussed above, the reason why θ1 and/or θ2 is made an acute angle is to secure a gap between a bit line contact 160 connecting the unit active region 103 and the bit line 170 and a storage node contact 180 (second contact plug in FIG. 6) connecting the unit active region 103 and a capacitor. θ1 and θ2 may be, for example, 45° and 45°, 30° and 60°, or 60° and 30° or other combination and are not limited thereto.

Referring now to FIG. 6, two first transistors TR1 may be formed in one unit active region 103. The two first transistors TR1 include a first impurity region 107a that is formed in the unit active region 103 between two first gate electrodes 130 and two first gate electrodes 130, which are formed to cross the unit active region 103, and a second impurity region 107b that is formed between the first gate electrode 130 and the isolation region 105. In other words, the two first transistors TR1 share the first impurity region 107a, but do not share the second impurity region 107b. The first impurity region 107a and the second impurity region 107b correspond to the first source/drain 107 illustrated in FIG. 1. The first transistor TR1 may include a first insulating film 120, a first gate electrode 130, a first work function adjustment film 135, and a first capping film 140.

As described above, the first insulating film 120 may be formed along the sidewall and the bottom surface of the first trench 110 formed in the substrate 100. The first work function adjustment film 135 may be formed on the first insulating film 120 along a part of the sidewall and the bottom surface of the first trench 110. The first gate electrode 130 may be formed on the first work function adjustment film 135, and may be formed so that it does not completely fill the first trench 110, but fills a part of the first trench 110. In other words, the first gate electrode 130 may be in a recessed shape. The first capping film 140 may be formed to fill the first trench 110 on the first work function adjustment film 135 and the first gate electrode 130.

The first work function adjustment film 135 includes a first upper work function adjustment film 135b and a first lower work function adjustment film 135a. The upper portion 130b of the first gate electrode overlaps the first upper work function adjustment film 135b, and the lower portion 130a of the first gate electrode overlaps the first lower work function adjustment film 135a.

The first gate electrode 130 may be formed using a conductive material, for example, metal. The first lower work function adjustment film 135a and the first upper work function adjustment film 135b may include the same metal. The first lower work function adjustment film 135a may include one nitride selected from the group including titanium (Ti), tantalum (Ta), tungsten (W), and titanium silicide (TiSi). The first upper work function adjustment film 135b includes a material obtained by oxidizing the first lower work function adjustment film 135a.

An interlayer insulating film 150 may be formed on the substrate 100. The interlayer insulating film 150 may include at least one of silicon oxide, silicon nitride, and silicon oxynitride. The interlayer insulating film 150 may be a single layer or a multilayer.

A first contact plug (bit line contact) 160 that is electrically connected to the first impurity region 107a may be formed in the interlayer insulating film 150. The first contact plug 160 may include a conductive material, and for example, may include at least one of polycrystalline silicon, metal silicide compound, and metal, but is not limited thereto. A bit line 170 that is electrically connected to the first impurity region 107a by the medium of the first contact plug 160 may be formed on the first contact plug 160. The bit line 170 may include a conductive material, and for example, may include at least one of polycrystalline silicon, metal silicide compound, conductive metal nitride, and metal, but is not limited thereto.

A second contact plug 180 may be formed in the interlayer insulating film 150 to penetrate the interlayer insulating film 150. The second contact plug 180 may be electrically connected to the second impurity region 107b. The second contact plug 180 may include a storage node contact. The second contact plug 180 may include a conductive material. For example, the second contact plug 180 may include at least one of polycrystalline silicon, metal silicide compound, conductive metal nitride, and metal, but is not limited thereto.

On the interlayer insulating film 150, an information storage portion, for example, a capacitor, that is electrically connected to the second impurity region 107b may be formed. The information storage portion may be electrically connected to the second impurity region 107b by the medium of the second contact plug 180.

In the semiconductor device 5 according to some embodiments of the present inventive concept, the GIDL characteristics of the first transistor TR1 can be improved using the first work function adjustment film 135 that includes the first upper work function adjustment film 135b and the first lower work function adjustment film 135a, which have different work functions.

FIGS. 5 and 6 illustrate that the semiconductor device as discussed above with reference to Figures is applied to the first transistor TR1, but is not limited thereto. In other words, the semiconductor devices as described above with reference to FIGS. 2-4 may be applied without departing from the scope of the present inventive concept.

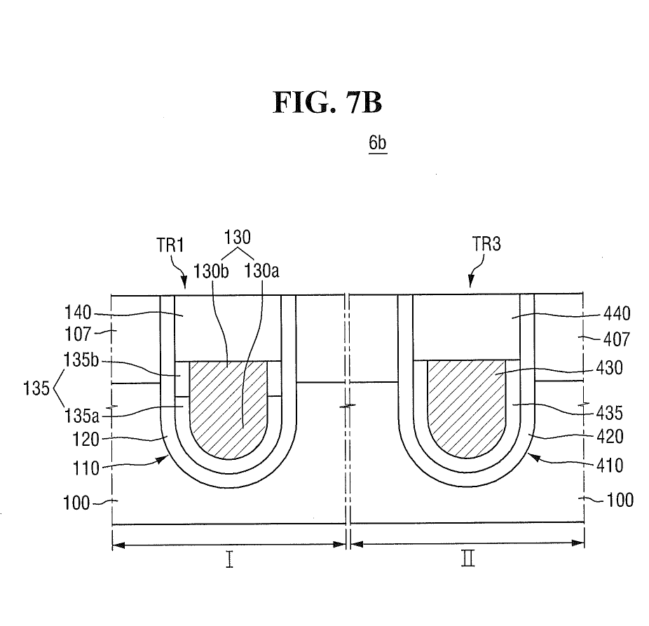

Referring now to FIGS. 7A and 7B, a semiconductor device according to some embodiments of the present inventive concept will be discussed. FIGS. 7A and 7B are cross-sections illustrating semiconductor devices according to some embodiments of the present inventive concept.

Referring first to FIG. 7A, a first region I and a second region II may be defined in the substrate 100. The first region I of the substrate 100 is a memory region, and the second region II of the substrate 100 is a peripheral circuit region. First transistors TR1 may be formed in the first region I that is the memory region, and second transistors TR2 may be formed in the second region II that is the peripheral circuit region. At least a part of the first transistors formed in the first region I may include the first work function adjustment films 135 having different work functions as described above.

The first transistor TR1 of the first region I may be, for example, an N-type transistor. In other words, the first source/drain 107 of the first transistor TR1 may include an N-type impurity. The second transistor TR2 in a planar shape may be formed in the second region II. The second transistor TR2 in the planar shape may include a source/drain 307, a spacer 315, a gate insulating film 320, and a gate electrode 330. The gate electrode 330 may be a silicon electrode, may be in a shape where silicon and metal are laminated, or may be formed of metal only, but is not limited thereto. Furthermore, a work function adjustment film may be further included between the gate electrode 330 and the gate insulating film 320.

As illustrated in FIG. 7B, the first region I of the substrate 100 may be a memory region, and the second region II of the substrate 100 may be a peripheral circuit region. The third transistor TR3 formed in the second region II may be a buried transistor. At least a part of the first transistors TR1 formed in the first region I may include the first work function adjustment films 135 including the first upper work function adjustment film 135b and the first lower work function adjustment film 135a which have different work functions as described above.

The first transistor TR1 of the first region I may be, for example, an N-type transistor. In other words, the first source/drain 107 of the first transistor TR1 may include an N-type impurity. In contrast, the third transistor TR3 of the second region II may be, for example, a P-type transistor. In other words, a third source/drain 407 of the third transistor TR3 may include a P-type impurity.

The third transistor TR3 may include a third insulating film 420, a second work function adjustment film 435, and a third gate electrode 430. The third insulating film 420 is formed on a third trench 410 formed in the second region II of the substrate 100. The second work function adjustment film 435 is formed on the third insulating film 420. The third gate electrode 430 is formed on the second work function adjustment film 435. The third gate electrode 430 is formed to fill a part of the third trench 410.

In the semiconductor device 6b according to some embodiments of the present inventive concept, the first work function adjustment film 135 that is included in the first transistor TR1 may be an N-type work function adjustment film, and the second work function adjustment film 435 that is included in the third transistor TR3 may be a P-type work function adjustment film. Although the first work function adjustment film 135 includes the first upper work function adjustment film 135b and the first lower work function adjustment film 135a, which have different work functions, the second work function adjustment film 435 may have one work function.

Referring again to FIG. 7B, the third transistor TR3 has the second work function adjustment film 435, but is not limited thereto. The third transistor TR3 may not include the second work function adjustment film 435.

As further illustrated in FIG. 7B, the first transistor TR1 is formed in the memory region, but is not limited thereto. In other words, the first region I and the second region II may be regions that are all included in the peripheral circuit region or regions that are included in the memory region.

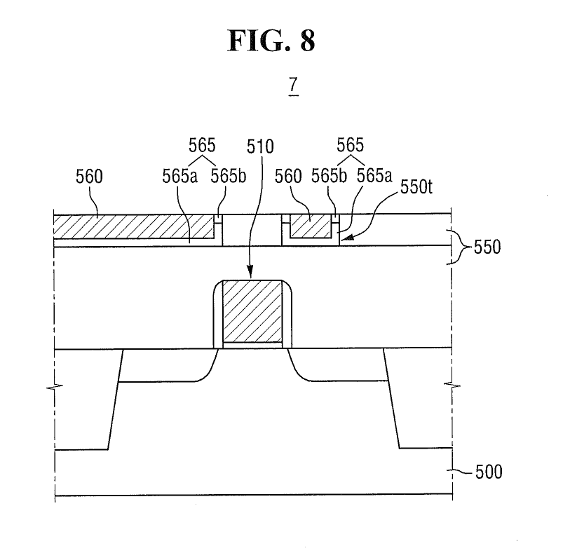

Referring now to FIG. 8, a semiconductor device according to some embodiments of the present inventive concept will be discussed. FIG. 8 is a cross-section illustrating a semiconductor device according to some embodiments of the present inventive concept. As illustrated in FIG. 8, a semiconductor device 7 includes a substrate 500, an interlayer insulating film 550, a fourth trench 550t, a barrier film 565, and a metal wiring 560.

A circuit pattern 510 may be formed on one surface of the substrate 500. The circuit pattern 510 may include transistors, diodes, and capacitors. The circuit patterns 510 may constitute circuit elements. Accordingly, the semiconductor device 7 may be a semiconductor chip in which a plurality of circuit elements are formed.

Although the device illustrated in FIG. 8 is a planar-shaped transistor, it will be understood that this is provided as an example of the circuit pattern 510 and that embodiments of the present inventive concept are not limited thereto.

The interlayer insulating film 550 may be formed on the substrate 500 and the circuit pattern 510. The interlayer insulating film 550 includes the fourth trench 550t formed in the interlayer insulating film 550. The interlayer insulating film 550 may include, for example, silicon oxide, silicon nitride, silicon oxynitride, or a low-k material. The low-k material may be, for example, FOX, TOSZ, USG, BSG, PSG, BPSG, PRTEOS, FSG, HDP, PEOX, FCVD, or a combination thereof. Although, the interlayer insulating film 550 is illustrated as a single layer, embodiments of the present inventive concept are not limited thereto. The interlayer insulating film 550 may be multiple layers without departing from the scope of the present inventive concept.

The barrier film 565 may be formed along a bottom surface and a sidewall of the fourth trench 550t. The barrier film 565 includes a lower barrier film 565a and an upper barrier film 565b. The lower barrier film 565a may be formed on the bottom surface of the fourth trench 550t and a lower portion of the sidewall of the fourth trench 550t, and the upper barrier film 565b may be formed on an upper portion of the sidewall of the fourth trench 550t. In other words, the sidewall of the fourth trench 550t may be divided into an upper portion and a lower portion around a boundary surface between the upper barrier film 565b and the lower barrier film 565a.

In some embodiments, the lower barrier film 565a and the upper barrier film 565b that constitute the barrier film 565 include the same metal, but include different materials. In particular, the lower barrier film 565a may include one nitride selected from the group including, for example, titanium (Ti), tantalum (Ta), tungsten (W), and titanium silicide (TiSi). However, the upper barrier film 565b includes a material obtained by oxidizing the lower barrier film 565a. In other words, the upper barrier film 565b may include, for example, one oxide or oxynitride selected from the group including titanium (Ti), tantalum (Ta), tungsten (W), and titanium silicide (TiSi). Although the barrier film 565 is illustrated as a single layer, it may be formed of a multilayer.

The metal wiring 560 is formed on the barrier film 565 to fill the fourth trench 550t. An upper surface of the metal wiring 560 and an upper surface of the interlayer insulating film 550 may be put on the same plane. The metal wiring 560 may include a conductive material, for example, one of tungsten (W), copper (Cu), and aluminum (Al).

While the upper barrier film 565b is formed, an impurity that is included in the metal wiring 560 may be removed, and the size of crystal grains of the conductive material that forms the metal wiring 560 is increased. Through this, the resistance of the metal wiring 560 may be decreased, and thus the characteristics of the semiconductor device 7 can be improved.

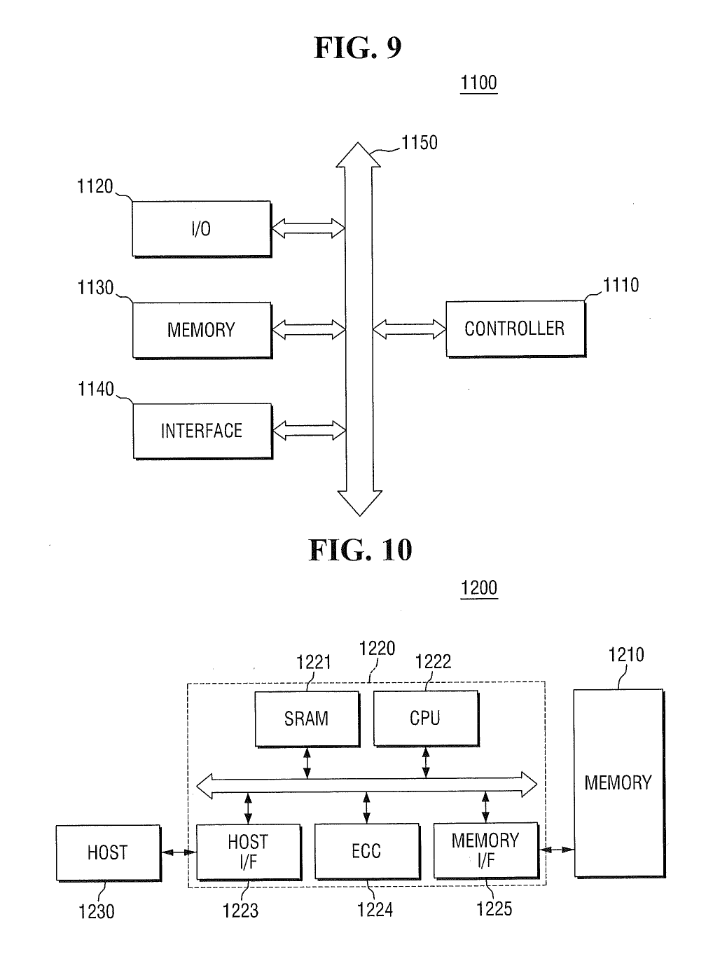

Referring now to FIG. 9, a block diagram illustrating an example of an electronic system including semiconductor devices according to some embodiments of the present inventive concept will be discussed. As illustrate in FIG. 9, an electronic system 1100 according to some embodiments of the present inventive concept may include a controller 1110, an input/output (I/O) device 1120, a memory 1130, an interface 1140, and a bus 1150. The controller 1110, the I/O device 1120, the memory 1130, and/or the interface 1140 may be coupled to one another through the bus 1150. The bus 1150 corresponds to paths through which data is transferred.

The controller 1110 may include at least one of a microprocessor, a digital signal processor, a microcontroller, and logic elements that can perform similar functions. The I/O device 1120 may include a keypad, a keyboard, and a display device. The memory 1130 may store data and/or commands. The memory 1130 may include semiconductor devices according to some embodiments of the present inventive concept. The memory 1130 may include a DRAM. The interface 1140 may function to transfer the data to a communication network or receive the data from the communication network. The interface 1140 may be of a wired or wireless type. For example, the interface 1140 may include an antenna or a wire/wireless transceiver.

The electronic system 1100 may be applied to a Personal Digital Assistant (PDA), a portable computer, a web tablet, a wireless phone, a mobile phone, a digital music player, a memory card, or all electronic devices that can transmit and/or receive information in wireless environments.

Referring now to FIG. 10, a block diagram illustrating an example of a memory card including semiconductor devices according to some embodiments of the present inventive concept will be discussed. As illustrated in FIG. 10, a memory 1210 that includes semiconductor devices according to various embodiments of the present inventive concept may be adopted in a memory card 1200. The memory card 1200 may include a memory controller 1220 that controls date exchange between a host 1230 and the memory 1210. An SRAM 1221 may be used as an operating memory of a central processing unit 1222. A host interface 1223 may include a protocol for the host 1230 to access the memory card 1200 to perform date exchange. An error correction code 1224 may detect and correct errors of data read from the memory 1210. A memory interface 1225 may interface with the memory 1210. The central processing unit 1222 may perform overall control operation related to data exchange with the memory controller 1220.

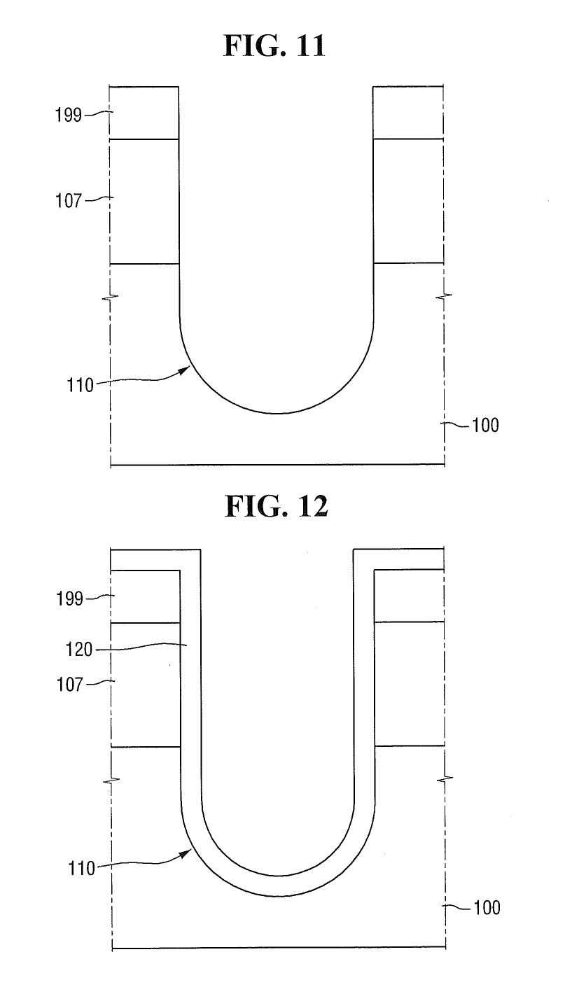

Referring now to FIGS. 1 and 11 to 16, cross-sections illustrating processing steps in the fabrication of semiconductor devices in accordance with some embodiments of the present inventive concept will be discussed. Referring first to FIG. 11, a first source/drain 107 is formed through injection of an impurity into a substrate 100. A first mask pattern 199 is formed on the substrate 100. The first mask pattern 199 exposes a region where a first trench 110 is to be formed. The first mask pattern 199 may be an oxide film, a nitride film, or an oxynitride film; however, embodiments of the present inventive concept are not limited thereto.

The first trench 110 is formed in the substrate 100 using the first mask pattern 199 as an etch mask. The first trench 110 may be formed using, for example, dry etching.

As illustrated in FIG. 12, a first insulating film 120 is formed on the first trench 110 along a sidewall and a bottom surface of the first trench. The first insulating film 120 may include at least one of silicon oxide, silicon nitride, silicon oxynitride, and a high-k material.

The first insulating film 120 may be formed using, for example, atomic layer deposition or chemical vapor deposition. If the first insulating film 120 includes a silicon oxide film, the silicon oxide film of the first insulating film 120 may be formed by thermal oxidation.

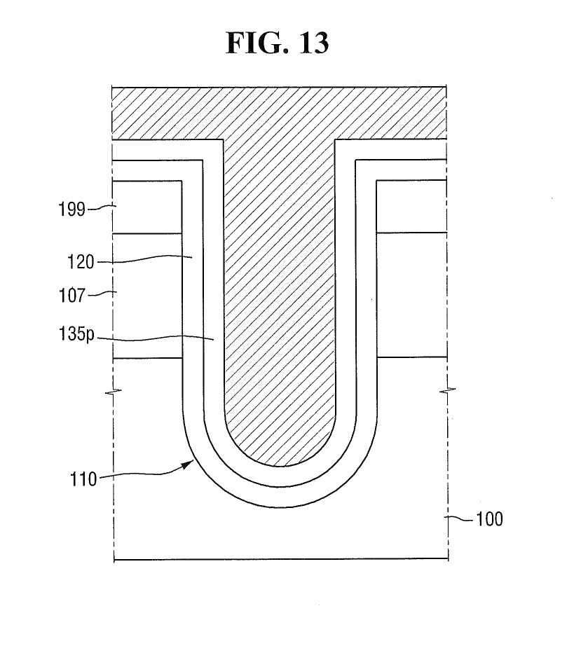

As illustrated in FIG. 13, a pre-work function adjustment film 135p and a first gate electrode film 130p are sequentially formed on the first insulating film 120. The pre-work function adjustment film 135p may be conformally formed along an upper surface and a sidewall of the first mask pattern 199 and the sidewall and the bottom surface of the first trench 110. The first gate electrode film 130p may fill the first trench 110 and may cover the upper surface of the first mask pattern 199.

The pre-work function adjustment film 135p may include one of TiN, TaN, Wn, and TiSiN. The first gate electrode film 130p may include a conductive material, for example, metal and polysilicon, and specifically, tungsten.

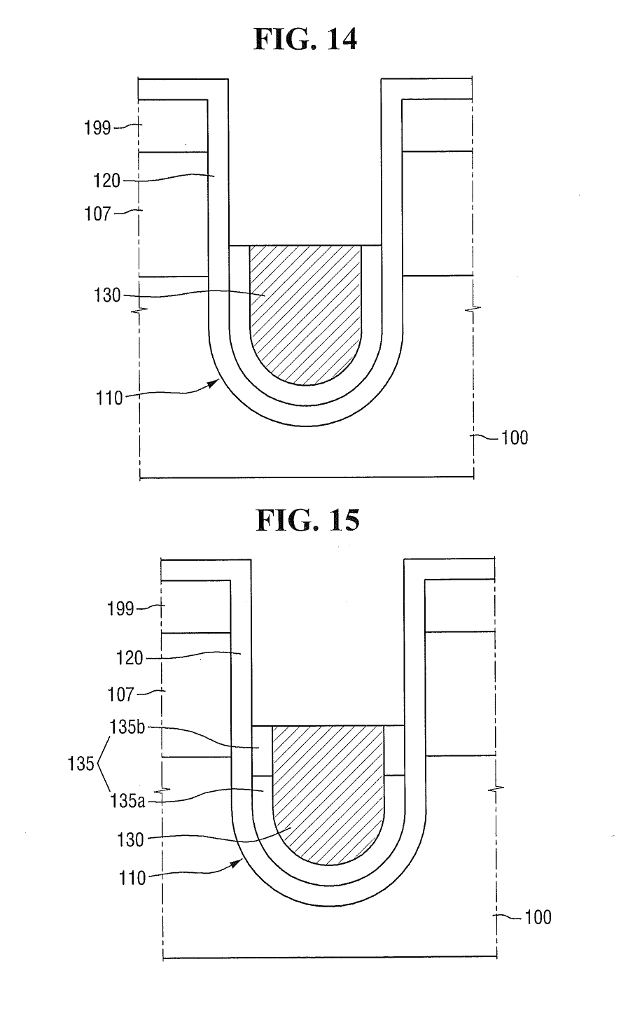

As illustrated in FIG. 14, by simultaneously etching the pre-work function adjustment film 135p and the first gate electrode film 130p, a first work function adjustment film 135 and a first gate electrode 130 may be formed. In other words, the recessed first work function adjustment film 135 and first gate electrode 130 are completed. An upper surface of the first gate electrode 130 may be lower than the upper surface of the substrate 100.

The first work function adjustment film 135 is formed along a part of the sidewall and the bottom surface of the first trench 110, and the first gate electrode 130 on the first work function adjustment film 135 fills a part of the first trench 110. The etching of the pre-work function adjustment film 135p and the first gate electrode film 130p may be performed using an etchback. The first work function adjustment film 135 and the first gate electrode 130 overlap a part of the first source/drain 107 formed on both sides of the first trench 110.

As illustrated in FIG. 14, the upper surface of the first gate electrode 130 and the upper surface of the first work function adjustment film 135 are put on the same plane; however, embodiments of the present inventive concept are not limited thereto.

Referring now to FIG. 15, by oxidizing a part of the first work function adjustment film 135, a first upper work function adjustment film 135b is formed. A non-oxidized portion of the first work function adjustment film 135 becomes a first lower work function adjustment film 135a. While the first upper work function adjustment film 135b is formed, an additional oxide film is not formed on the upper portion of the sidewall of the first trench 110 that does not overlap the first work function adjustment film 135 and the upper surface of the first mask pattern 199.

The first upper work function adjustment film 135b may be formed using, for example, a selective oxidization process. While the first upper work function adjustment film 135b is formed, the first gate electrode 130 is not oxidized, and thus it may be considered as a selective oxidization process.

The first upper work function adjustment film 135b may be formed using, for example, a plasma oxidization process or a thermal oxidization process.

In embodiments using the plasma oxidization process, by injecting a gas including a small amount of oxygen in hydrogen gas atmosphere, the upper portion of the first work function adjustment film 135 may be oxidized into the first upper work function adjustment film 135b. In particular, in the plasma oxidization process, mixed gas of a first gas including hydrogen and a second gas including oxygen may be used. The first gas including hydrogen may include, for example, hydrogen or heavy hydrogen. The second gas including oxygen may include, for example, O₂, O₃, NO, N₂O, or H₂O. In addition, the mixed gas that is used in the plasma oxidization process may include a gas including nitrogen, for example, N2 or NH3, or an inert gas as a dilution gas.

Only an upper portion of the first work function adjustment film 135 should be selectively oxidized. For this, in the mixed gas that is used in the plasma oxidization process, the rate of the first gas including hydrogen is higher than the rate of the second gas including oxygen. In other words, in the mixed gas that is used in the plasma oxidization process, partial pressure of the first gas including hydrogen is higher than partial pressure of the second gas including oxygen.

In order to control the height of the first upper work function adjustment film 135b, a bias may be applied to the substrate 100 during the plasma oxidization process. By applying the bias to the substrate 100, the height h2 (in FIG. 1) of the first upper work function adjustment film 135b that is formed through oxidization of the first work function adjustment film 135 is also increased.

Before or after the first upper work function adjustment film 135b is formed, an additional nitrization process may be performed. The nitrization process may be performed using, for example, N₂, NH₃, NO, or N₂O gas as a plasma source gas.

While the first work function adjustment film 135b is formed, the first insulating film 120 that does not overlap the first work function adjustment film 135 may be cured. In other words, in the etching process for forming the first work function adjustment film 135 and the first gate electrode 130, a defect may occur on the surface of the first insulating film 120. The defect occurring as described above may exert an influence on the performance of the semiconductor device. Accordingly, through a process of forming the first upper work function adjustment film 135b, for example, a plasma oxidization process or thermal oxidization process, the defect that has occurred on the first insulating film 120 can be cured.

Furthermore, through the plasma oxidization process for forming the first upper work function adjustment film 135b, the first gate electrode 130 is cured, and thus the resistance thereof can be decreased. In particular, hydrogen-excited hydrogen radical or heavy hydrogen radical included in the source gas of the plasma oxidization process may remove the impurity included in the first gate electrode 130. The impurity included in the first gate electrode 130 may flow into the film in the process of forming the first gate electrode film 130p. Furthermore, through the plasma oxidization process for forming the first upper work function adjustment film 135b, the size of grains of the material that forms the first gate electrode 130 is increased. Due to this effect, the resistance of the first gate electrode 130 may be decreased.

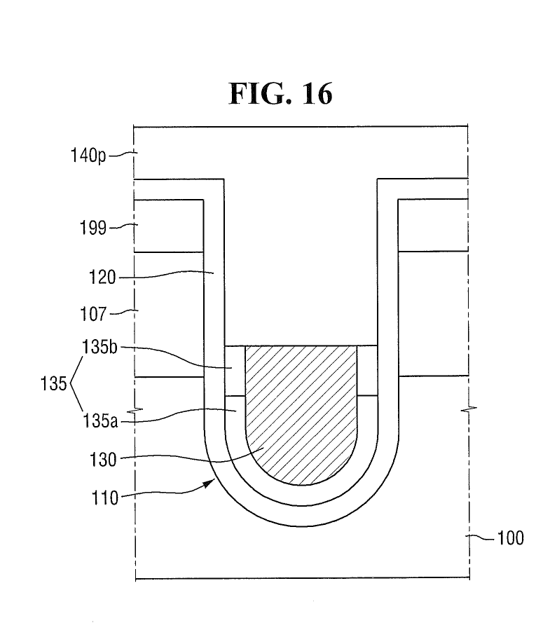

Referring now to FIG. 16, the first pre-capping film 140p is formed on the first gate electrode 130 and the first upper work function adjustment film 135b to fill the first trench 110. The first pre-capping film 140p may also be formed on the upper surface of the first mask pattern 199. The first pre-capping film 140p may be, for example, a silicon oxide film, a silicon nitride film, or a silicon oxynitride film, but is not limited thereto.

Referring again to FIG. 1, the upper surface of the substrate 100 may be exposed through removal of a part of the first pre-capping film 140p and the first mask pattern 199.

In particular, using a planarization process, a part of the first pre-capping film 140p and the whole of the first mask pattern 199 may be removed. At this time, a part of the first insulating film 120 that is formed on the upper surface and the sidewall of the first mask pattern 199 is removed. As a result, the first insulating film 120 remains only on the sidewall and the bottom surface of the first trench 110 that is formed in the substrate. The first insulating film 120 is not formed on the upper surface of the substrate 100.

Referring to FIGS. 4, 11, 12, and 17 to 19, processing steps in the fabrication of semiconductor devices according to some embodiments of the present inventive concept will be discussed. Referring first to FIGS. 11, 12, and 17, a second insulating film 220 is formed on a second trench 210 formed in a substrate 200 along a sidewall and a bottom surface of the second trench 210. A second gate electrode film 230p that fills the second trench 210 is formed on the second insulating film 220.

The second insulating film 220 may include at least one of silicon oxide, silicon nitride, silicon oxynitride, and a high-k material. The second insulating film 220 may be formed using, for example, atomic layer deposition or chemical vapor deposition. If the second insulating film 220 includes a silicon oxide film, the silicon oxide film of the second insulating film 220 may be formed by thermal oxidation.

The second gate electrode film 230p may fill the second trench 210 and may cover an upper surface of a second mask pattern 299. The second gate electrode film 230p may include, for example, one of TiN, TaN, WN, and TiSiN.

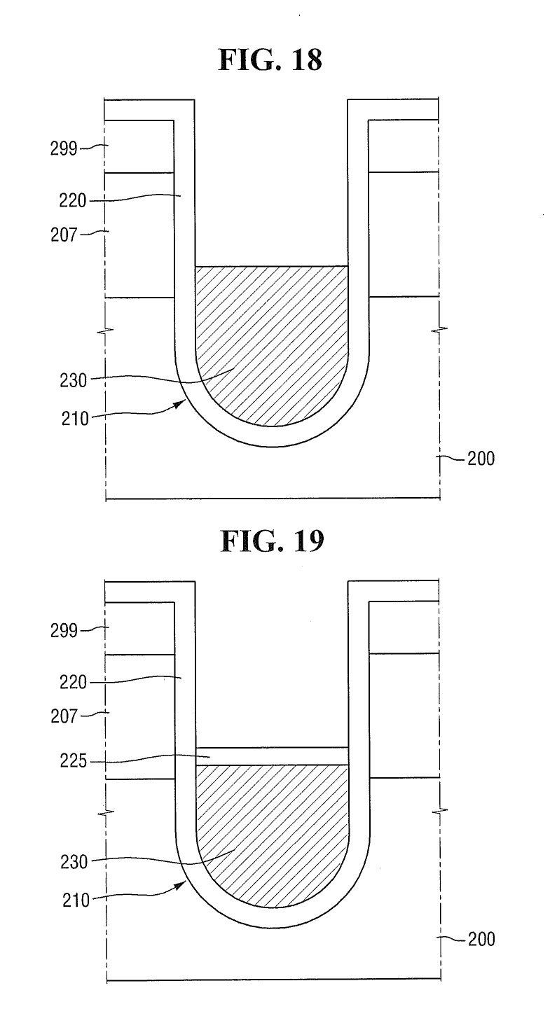

Referring now to FIG. 18, a second gate electrode 230 may be formed through etching of the second gate electrode film 230p. In other words, the recessed second gate electrode 230 is completed. An upper surface of the second gate electrode 230 may be lower than the upper surface of the substrate 200. The second gate electrode film 230p may be etched using, for example, an etchback. The recessed second gate electrode 230 overlaps a part of a second source/drain 207 formed on both sides of the second trench 210.

Referring now to FIG. 19, an electrode oxide film 225 is formed on the second gate electrode 230 through oxidization of a part of the second gate electrode 230. The electrode oxide film 225 may be formed through oxidization of the upper portion of the second gate electrode 230.

The electrode oxide film 225 may be formed using, for example, a plasma oxidization process or a thermal oxidization process. In embodiments where the electrode oxidization film 225 is formed using the plasma oxidization process, in the mixed gas that is used in the plasma oxidization process, the partial pressure of a gas including hydrogen may be higher than the partial pressure of a gas including oxygen.

While the electrode oxide film 225 is formed, a defect of the second insulating film 220 that does not overlap the second gate electrode 230 and the electrode oxide film 225 may be cured.

As illustrated in FIG. 19, the electrode oxide film 225 overlaps the second source/drain 207 formed on both sides of the second trench 210 as a whole, but is not limited thereto.

Referring to FIG. 4, a second capping film 240 that fills the second trench 210 on the electrode oxide film 225 may be formed. The second capping film 240 may be, for example, an oxide film, a nitride film, or an oxynitride film, but is not limited thereto.

In particular, a second pre-capping film that fills the second trench 210 is formed on the electrode oxide film 225. Using a planarization process, a part of the second pre-capping film and the whole of the second mask pattern 299 may be removed. At this time, a part of the second insulating film 220 that is formed on the upper surface and the sidewall of the second mask pattern 299 may be removed.

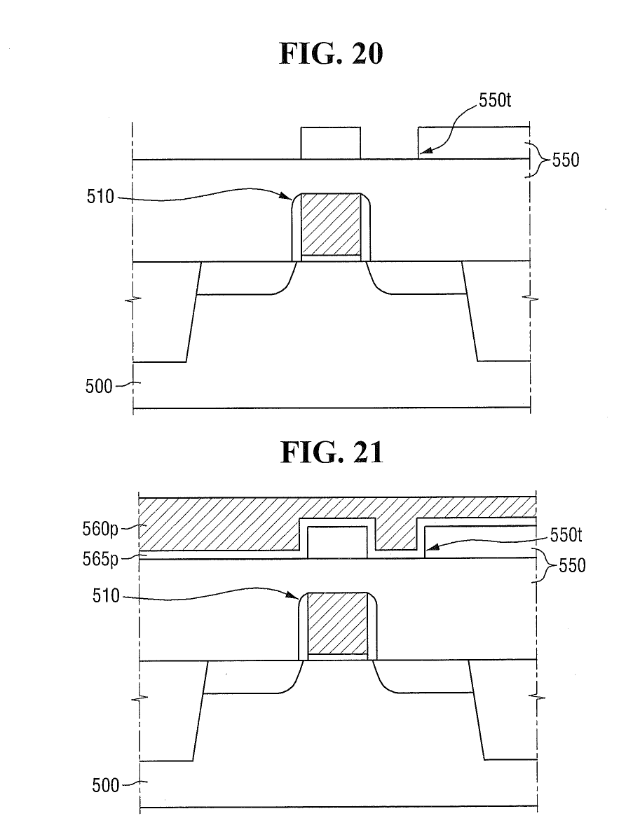

Referring to FIGS. 8 and 20 to 22, processing steps in the fabrication of semiconductor devices according to some embodiments of the present inventive concept will be discussed. Referring first to FIG. 20, a circuit pattern 510 is formed on and/or in a substrate 500. An interlayer insulating film 550 is formed on the substrate 500 on which the circuit pattern 510 is formed. A mask pattern is formed on the interlayer insulating film 550, and a fourth trench 550t is formed in the interlayer insulating film 550 using the mask pattern.

The circuit pattern 510 may include transistors, diodes, and capacitors. The circuit patterns 510 may constitute circuit elements. The interlayer insulating film 550 may include silicon oxide, silicon nitride, silicon oxynitride, or a low-k material. The low-k material may be, for example, FOX, TOSZ, USG, BSG, PSG, BPSG, PRTEOS, FSG, HDP, PEOX, FCVD, or a combination thereof. The interlayer insulating film 550 may be a single layer or a multiple layers without departing from the scope of the present inventive concept.

Referring to FIG. 21, a pre-barrier film 565p is conformally formed on a sidewall and a bottom surface of the fourth trench 550t and an upper surface of the interlayer insulating film 550. A metal wiring film 560p is formed on the pre-barrier film 565p. The metal wiring film 560p may fill the fourth trench 550t and may be formed even on the upper surface of the interlayer insulating film 550.

The pre-barrier film 565p may include one of, for example, TiN, TaN, WN, TiSiN, and a combination thereof. The pre-barrier film 565p may be formed using, for example, atomic layer deposition or chemical vapor deposition.

The metal wiring film 560p may include, for example, one of Al, Cu, W, and a combination thereof. The metal wiring film 560p may be formed using chemical vapor deposition, sputtering, or electroplating.

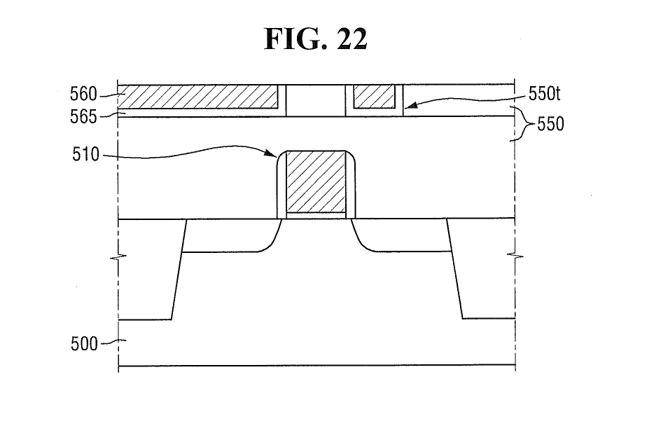

Referring to FIG. 22, by removing a part of the metal wiring film 560p and the pre-barrier film 565p, a barrier film 565 and a metal wiring 560 are formed in the interlayer insulating film 550.

In particular, the pre-barrier film 565p and the metal wiring film 560p formed on the upper surface of the interlayer insulating film 550 are removed using a planarization process. Through this, the upper surface of the interlayer insulating film 550 is exposed, and the barrier film 565 and the metal wiring 560, which are sequentially laminated in the fourth trench 550t, are completed.

Referring again to FIG. 8, an upper barrier film 565 is formed through oxidization of a part of the barrier film 565 that is exposed through an oxidization process. A part of the non-oxidized barrier layer 565 becomes a lower barrier film 565. In some embodiments, the upper barrier film may be formed using a plasma oxidization process or a thermal oxidization process.

The lower barrier film 565a and the upper barrier film 565b that constitute the barrier film 565 include the same metal, but include different materials. The upper barrier film 565b includes a material obtained by oxidizing the lower barrier film 565a.

While the upper barrier film 565b is formed, an impurity that is included in the metal wiring 560 may be removed, and the size of crystal grains of the conductive material that forms the metal wiring 560 may be increased to reduce the resistance of the metal wiring 560.

Although some embodiments of the present inventive concept have been described for illustrative purposes, those skilled in the art will appreciate that various modifications, additions and substitutions are possible, without departing from the scope and spirit of the inventive concept as disclosed in the accompanying claims.

What is claimed is:

1. A semiconductor device comprising:
a first trench in a semiconductor substrate;
a first insulating film in the first trench;
a first conductive film on the first insulating film, the first conductive film having upper and lower portions and filling at least a portion of the first trench; and
a first work function adjustment film having first and second portions, a first lower work function adjustment film portion and a first upper work function adjustment portion, the first lower work function adjustment film portion overlapping the lower portion of the first conductive film and the first upper work function adjustment film portion overlapping the upper portion of the first conductive film between the first insulating film and the first conductive film.

2. The semiconductor device of claim 1, wherein a first work function of the first lower work function adjustment film portion is larger than a second work function of the first upper work function adjustment film portion.

3. The semiconductor device of claim 1, wherein an upper surface of the first conductive film is free of the first upper work function adjustment film.

4. The semiconductor device of claim 1, wherein profiles of both side surfaces of the first lower work function adjustment film portion and the first upper work function adjustment film portion are continued.

5. The semiconductor device of claim 1, further comprising an impurity region on both sides of the first trench, wherein the first upper work function adjustment film portion overlaps the impurity region.

6. The semiconductor device of claim 5:
wherein a depth from an upper surface of the semiconductor substrate to a bottom surface of the impurity region is a first depth;
wherein a depth from the upper surface of the substrate to the lowermost portion of the first upper work function adjustment film is a second depth; and
wherein the second depth is larger than the first depth.

7. The semiconductor device of claim 1, wherein the first lower work function adjustment film portion includes a material including one of Ti, Ta, W, and TiSi.

8. The semiconductor device of claim 7, wherein the first upper work function adjustment film portion includes a material that is an oxidized version of the material of lower work function adjustment film portion.

9. The semiconductor device of claim 1:
wherein a height of an upper portion of the first conductive film is a first height;
wherein a height of the first upper work function adjustment film is a second height; and
wherein the first height and the second height are substantially the same.

10. The semiconductor device of claim 1, wherein the first insulating film includes silicon oxide.

11. The semiconductor device of claim 1:
wherein the semiconductor substrate comprises first and second regions; and
wherein the first trench, the first insulating film, the first work function adjustment film, and the first conductive film are in the first region, the semiconductor device further comprising:
a second trench in the second region;
a second insulating film in the second trench;
a second conductive film on the second insulating film and filling at least a portion of the second trench;
a second work function adjustment film between the second insulating film and the second conductive film,
wherein the second trench, the second insulating film, the second conductive film and the second work function adjustment film are in the second region of the semiconductor substrate; and
wherein the first work function adjustment film is an n-type work function adjustment film and the second work function adjustment film is a p-type work function adjustment film.

12. A semiconductor device comprising:
a trench in a semiconductor substrate;
a first insulating film in the trench;
a first conductive film on the first insulating film, the first conductive film having upper and lower portions and filling a portion of the trench;
a second conductive film, overlapping the lower portion of the first conductive film between the first insulating film and the first conductive film; and
a second insulating film including a material including an oxidized version of a material of the second conductive film and overlapping the upper portion of the first conductive film between the first insulating film and the first conductive film.

13. The semiconductor device of claim 12, wherein an upper surface of the first conductive film is free of the second insulating film.

14. The semiconductor device of claim 12, wherein profiles of both side surfaces of the second insulating film and the second conductive film are continued.

15. The semiconductor device of claim 12, further comprising an impurity region on both sides of the trench, wherein the second insulating film overlaps the impurity region.

16. A semiconductor device comprising:
a semiconductor substrate defining a trench; and
a gate electrode in the trench having a first portion and a second portion on the first portion, the first portion of the gate electrode including a first material and the second portion of the gate electrode including an oxidized version of the first material.

17. The semiconductor substrate of claim 16, further comprising a work function adjustment film in the trench between the semiconductor substrate and the gate electrode,
wherein the work function adjustment film has a first portion and a second portion on the first portion;
wherein the first portion of the gate electrode is adjacent the first portion of the work function adjustment film; and
wherein the second portion of the gate electrode is adjacent the second portion of the work function adjustment film.

18. The semiconductor device of claim 17, wherein a height of the second portion of the gate electrode and a height of the second portion of the work function adjustment film are substantially equal.

19. The semiconductor device of claim 18, wherein a work function of the first portion of the work function adjustment film is different from a work function of the second portion of the work function adjustment film.

20. The semiconductor device of claim 19, wherein the work function of the first portion of the work function adjustment film is larger than the work function of the second portion of the work function adjustment film.
